(19) United States
(12) Patent Application Publication
(10) Pub. No.: US 2026/0362702 A1
(43) Pub. Date: Nov. 12, 2026

(54) HYBRID MEMORY DEVICE

(71) Applicants: Materials Analysis Technology Inc., HSINCHU COUNTY (TW); National Tsing Hua University, Hsinchu City (TW)

(72) Inventors: Yung-Hsien Wu, Hsinchu City (TW); Kai-Yang Huang, Kaohsiung City (TW); Yi-Fan Chen, New Taipei City (TW); Chun-Yi Kuo, Hsinchu City (TW); Hung-Jen Chen, Hsinchu City (TW)

(73) Assignees: Materials Analysis Technology Inc., HSINCHU COUNTY (TW); National Tsing Hua University, Hsinchu City (TW)

(21) Appl. No.: 19/287,751

(22) Filed: Jul. 31, 2025

Related U.S. Application Data
(60) Provisional application No. 63/801,145, filed on May 7, 2025.

(30) Foreign Application Priority Data
Jul. 18, 2025 (TW) 114127215

(51) Int. Cl. H10B 51/30

(52) U.S. Cl. CPC H10B 51/30

(57) ABSTRACT

Provided is a hybrid memory device, which includes a semiconductor substrate, a tunneling layer, a ferroelectric storage layer, a gate, and multiple doped regions. The tunneling layer is disposed on the semiconductor substrate. The ferroelectric storage layer is disposed on the tunneling layer to enhance an electric field of the tunneling layer. The ferroelectric storage layer includes a ferroelectric material having electron storing characteristics and ferroelectric characteristics. The gate is disposed on the ferroelectric storage layer. The gate is in direct contact with the ferroelectric storage layer. The doped regions are formed in the semiconductor substrate at both sides of the gate.

### CROSS-REFERENCE TO RELATED APPLICATION

This application claims the priority benefit of U.S. provisional application serial no. 63/801,145, filed on May 7, 2025, and Taiwan application serial no. 114127215, filed on Jul. 18, 2025. The entirety of each of the above-mentioned patent applications is hereby incorporated by reference herein and made a part of this specification.

### BACKGROUND

### Technical Field

The disclosure relates to a semiconductor memory technology, and particularly relates to a hybrid memory device.

### Related Art

Flash memory is a type of non-volatile memory that currently dominates the non-volatile memory market. Despite significant advances, flash memory still has the disadvantage of a high operating voltage (> 20 V) and a slow operating speed (approximately 1 ms).

On the other hand, ferroelectric field-effect transistor (FeFET) memory is an emerging type of non-volatile memory that not only has excellent energy efficiency and CMOS compatibility, but also demonstrates the application potential in associative search and memory computing acceleration. However, FeFET memory has the problem that read delay after write may not be shortened.

Therefore, there is an urgent need to develop non-volatile memory that solves the foregoing problems.

### SUMMARY

The disclosure provides a hybrid memory device, which can reduce an operating voltage and improving an operating speed, and obtain excellent effects in read speed and reliability at the same time.

The hybrid memory device of the disclosure includes a semiconductor substrate, a tunneling layer, a ferroelectric storage layer, a gate, and multiple doped regions. The tunneling layer is disposed on the semiconductor substrate. The ferroelectric storage layer is disposed on the tunneling layer to enhance an electric field of the tunneling layer. The ferroelectric storage layer includes a ferroelectric material. The gate is disposed on the ferroelectric storage layer. The gate is in direct contact with the ferroelectric storage layer. The doped regions are formed in the semiconductor substrate on both sides of the gate.

In an embodiment of the disclosure, the ferroelectric material includes hafnium oxide doped with a metal.

In an embodiment of the disclosure, the semiconductor substrate includes a silicon substrate or a germanium substrate.

In an embodiment of the disclosure, the tunneling layer includes a single-layer or multi-layer structure.

In an embodiment of the disclosure, the gate includes a metal gate or a titanium nitride gate.

In an embodiment of the disclosure, the tunneling layer includes a high dielectric constant (high-k) material.

Based on the above, the disclosure utilizes the ferroelectric material to serve as a charge capture layer of flash memory, which can overcome a limitation of excessive operating voltage and slow operating speed of conventional flash memory, and can further overcome a limitation of current FeFET ferroelectric memory in read operation and reliability. The hybrid memory device of the disclosure is expected to achieve a multi-bit storage operation of 2 bits or more and have a capability for future computing-in-memory (CIM) applications.

In order to make the features and advantages of the disclosure more comprehensible, the following examples are given and described in detail with the accompanying drawings as follows.

### BRIEF DESCRIPTION OF THE DRAWINGS

FIG. 1 is a schematic cross-sectional view of a hybrid memory device according to a first embodiment of the disclosure.

FIG. 2 is a graph of polarization-voltage (P-V) curves of Comparative Example, Experimental Example 1, and Experimental Example 2.

FIG. 3 is a graph of I_{D}-V_{GS} curves of Comparative Example, Experimental Example 1, and Experimental Example 2.

FIG. 4 is a band diagram of the gates in the devices of Comparative Example and Experimental Example 1 under a positive bias.

FIG. 5 is a band diagram of the gates in the devices of Comparative Example and Experimental Example 1 under a negative bias.

FIG. 6 is a curve graph of threshold voltages (Vt) changing with a pulse width for the devices of Comparative Example and Experimental Example 1.

FIG. 7 is a curve graph of switchable polarizations changing with a pulse width for the device of Experimental Example 1.

FIG. 8 is a curve graph of short-term delay in read-after-write for the devices of Comparative Example and Experimental Example 1.

FIG. 9 is a curve graph of long-term delay in read-after-write for the devices of Comparative Example and Experimental Example 1.

FIG. 10 is a graph of Vt curves of the devices of Comparative Example and Experimental Example 1 after an endurance test.

FIG. 11 is a graph of endurance characteristics of the device of Experimental Example 1 after 10⁵ cycles in different Vt states.

FIG. 12 is a distribution graph of Vt of the device of Experimental Example 1 after 10⁵ cycles in different Vt states.

FIG. 13 is a graph of an excitatory postsynaptic current (EPSC) curve of the device of Experimental Example 1.

FIG. 14 is a graph of an inhibitory postsynaptic current (IPSC) curve of the device of Experimental Example 1.

### DESCRIPTION OF THE EMBODIMENTS

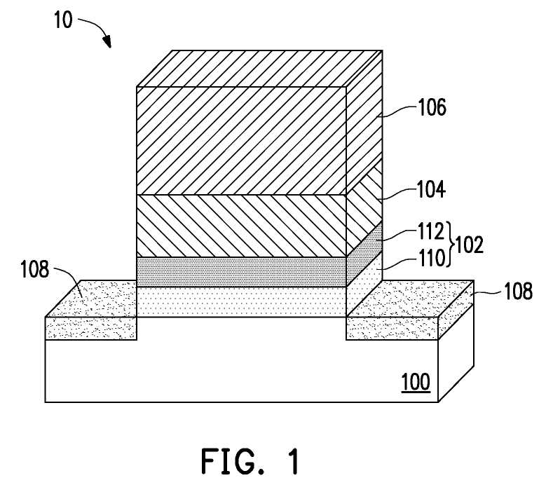

FIG. 1 is a schematic cross-sectional view of a hybrid memory device according to a first embodiment of the disclosure.

Referring to FIG. 1, a hybrid memory device 10 of the first embodiment includes a semiconductor substrate 100, a tunneling layer 102, a ferroelectric storage layer 104, a gate 106, and multiple doped regions 108. The tunneling layer 102 is disposed on the semiconductor substrate 100. The ferroelectric storage layer 104 is disposed on the tunneling layer 102 to enhance an electric field of the tunneling layer 102. The ferroelectric storage layer 104 includes a ferroelectric material. The gate 106 is disposed on the ferroelectric storage layer 104. The gate 106 is in direct contact with the ferroelectric storage layer 104. The doped regions 108 are formed in the semiconductor substrate 100 on both sides of the gate 106, which may serve as a source and a drain of the hybrid memory device 10, allowing an operation of the hybrid memory device 10 to follow an operation mode of flash memory.

In some embodiments, the ferroelectric material in the ferroelectric storage layer 104 may be hafnium oxide doped with a metal, which includes hafnium zirconium oxide (HZO), hafnium aluminum oxide (HAO), hafnium silicon oxide (HSO), or hafnium oxide doped with other metals. Available dopants, such as scandium (Sc), lanthanum (La), calcium (Ca), barium (Ba), yttrium (Y), strontium (Sr), and/or gadolinium (Gd). In some other embodiments, the foregoing ferroelectric material may include lead zirconate titanate (PZT), lead zirconate titanate (PLZT) doped with lanthanum, lead zirconate (PBT), barium titanate (BaTiO₃), lead titanate (PbTiO₃), lead metaniobate (PbNb₂O₆), lithium niobate (LiNbO₃), lithium tantalate (LiTaO₃), lead magnesium niobate (PMN), lead scandium tantalate (PST), strontium bismuth tantalate (SBT), bismuth sodium titanate (BNT), aluminum scandium nitride (AlScN), or aluminum nitride (AlN). The ferroelectric material in the ferroelectric storage layer 104, due to a dipole effect, may store electrons and has ferroelectric characteristics, thereby reducing an electric field distribution. That is to say, an electric field applied to the gate 106 is more easily dropped across this thin film layer, allowing an operating voltage to be lower and improving an operating speed.

In some embodiments, the semiconductor substrate 100 includes a silicon (Si) substrate or a germanium (Ge) substrate. In embodiments where the semiconductor substrate 100 is a silicon substrate, the tunneling layer 102 is a single-layer structure (not shown). The single-layer structure is, for example, a silicon oxide layer or a silicon oxynitride layer, but is not limited thereto. The silicon substrate may also be in conjunction with a multi-layer structure tunneling layer 102, such as an oxide-nitride-oxide (ONO) structure. In examples where the semiconductor substrate 100 is a germanium substrate, the tunneling layer 102 may be a multi-layer structure, such as a germanium oxide layer 110 connected to the germanium substrate, and a high dielectric constant (high-k) material layer 112 between the germanium oxide layer 110 and the ferroelectric storage layer 104. Since a surface of the germanium substrate has defects, pre-growing the germanium oxide layer 110 may improve an interface between the semiconductor substrate 100 and an upper layer thereof. As for the high-k material layer 112 formed on the germanium oxide layer 110, since there is a larger energy gap, electrons are not easily released after being stored. The “high-k material” in the text represents a material having a higher dielectric constant compared to silicon dioxide, and is typically a material with a dielectric constant greater than approximately 3.9, and may be a material with a dielectric constant greater than approximately 7.0. In some embodiments, a material of the high-k material layer 112 includes metal oxides or metal nitrides, such as zirconium oxide, aluminum oxide, hafnium oxide, silicon nitride, silicon oxynitride, hafnium nitride (HfN), titanium oxide, tantalum oxide, zirconium oxide, zirconium silicon oxide, lanthanum oxide, yttrium oxide, strontium titanate, barium titanate, barium zirconate, lanthanum silicon oxide, aluminum silicon oxide, hafnium tantalum oxide, hafnium titanium oxide, or a combination thereof. A germanium channel formed in the germanium substrate has more thermally excited free carriers than a channel formed in the silicon substrate, reducing a depolarization field and enhancing a memory window (MW). In some embodiments, the semiconductor substrate 100 is a p-type substrate, and the doped regions 108 are n-type regions. In some other embodiments, the semiconductor substrate 100 is an n-type substrate, and the doped regions 108 are p-type regions.

In some embodiments, the gate 106 includes a metal gate or a gate that includes a metal. A material of the gate 106 includes but is not limited to titanium (Ti), titanium nitride (TiN), tantalum (Ta), tantalum nitride (TaN), tungsten (W), tungsten nitride (WN), platinum (Pt), copper (Cu), aluminum (Al), iron (Fe), nickel (Ni), cobalt (Co), chromium (Cr), beryllium (Be), antimony (Sb), iridium (Ir), molybdenum (Mo), ruthenium (Ru), osmium (Os), thorium (Th), vanadium (V), or an alloy thereof. In some embodiments, if the metal gate (such as a tungsten gate) is selected for the gate 106, ferroelectric characteristics may be strengthened. Since the ferroelectric storage layer 104 serving as a charge capture layer has ferroelectricity, an electric dipole thereof may more effectively preserve captured electrons. Therefore, a blocking layer such as oxide layers is not needed to be disposed between the gate 106 and the ferroelectric storage layer 104, while still maintaining excellent data endurance and may further reduce the operating voltage.

Please continue to refer to FIG. 1. Although each layer structure in the hybrid memory device 10 is not drawn to scale, a relative thickness of each layer may still be referenced from the figure. For example, the ferroelectric storage layer 104 is thicker than the tunneling layer 102, the gate 106 is thicker than the ferroelectric storage layer 104, and both the germanium oxide layer 110 and the high k material layer 112 in the tunneling layer 102 are approximately several nanometers thick. A thickness of the germanium oxide layer 110 is not greater than a thickness of the high k material layer 112.

Each layer in the hybrid memory device 10 may be formed using atomic layer deposition (ALD), so the hybrid memory device 10 may basically be manufactured within a same machine. However, the disclosure is not limited thereto. In some embodiments, each layer in the hybrid memory device 10 may be deposited using different processes.

The following experiments are listed to verify the implementation effects of the disclosure. However, the disclosure is not limited to the following content.

### Experimental Example 1

On a p-type Ge substrate, an ALD equipment is used to continuously grow/deposit a 0.5 nm thick germanium oxide (GeO₂) layer, a 1.2 nm thick aluminum oxide (Al₂O₃) layer, and a 6.5 nm thick HZO layer. The germanium oxide layer and the aluminum oxide layer serve as a tunneling layer, and the HZO layer serves as a ferroelectric storage layer.

Then, a 50 nm thick TiN layer is deposited and patterned to form a TiN metal gate. Subsequently, phosphorus (P) injection is performed to form a source/a drain in the p-type Ge substrate on both sides of the TiN metal gate. Finally, rapid thermal annealing (RTA) is performed at 500° C. to activate the dopant while crystallizing the HZO, finally completing a hybrid memory device of Experimental Example 1 (labeled as AlO/HZO).

### Experimental Example 2

The same process as Experimental Example 1 is utilized, but the aluminum oxide layer is replaced with an HfN layer. A finally completed hybrid memory device of Experimental Example 2 is labeled as HfN/HZO.

### Comparative Example

The same process as Experimental Example 1 is utilized, but the HZO layer is replaced with a hafnium oxide (HfO₂) layer. A finally completed memory device of the comparative example is labeled as AlO/HfO.

### Performance Evaluation

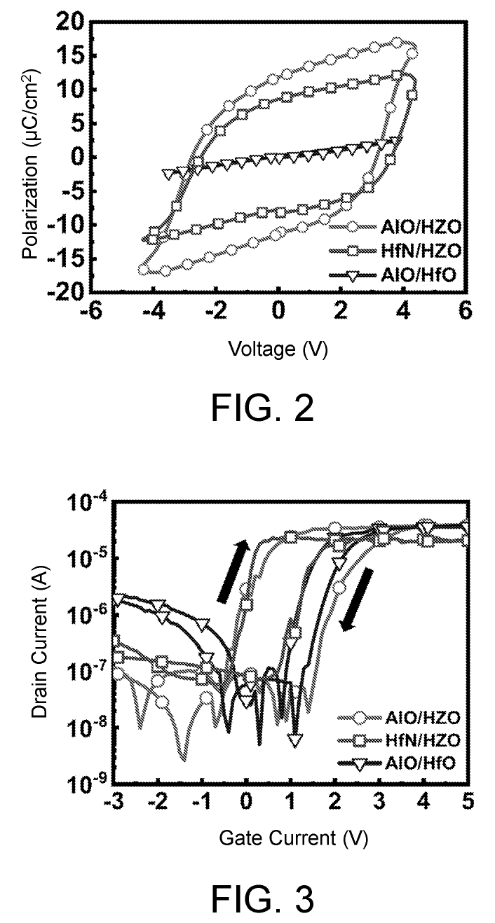

FIG. 2 is P-V curves of all the foregoing devices. The AlO/HZO device (Experimental Example 1) and the HfN/HZO device (Experimental Example 2) have obvious polarization (Pr) changes. The AlO/HfO device (Comparative Example) has no ferroelectric characteristics.

FIG. 3 is a graph of I_{D}-V_{GS} curves for applying a 5 V/-3 V pulse continuously for 1 μs on all the foregoing devices. From FIG. 3, it may be obtained that for the AlO/HZO device (Experimental Example 1) and the HfN/HZO device (Experimental Example 2), a positive Vt offset of +5 V represents that a memory operation mechanism of HZO is electron capturing rather than electric dipole direction switching. In other words, the operations of Experimental Example 1 and Experimental Example 2 are similar to flash memory, rather than typical ferroelectric memory. Moreover, a maximum MW of Experimental Example 1 is 2.2 V, which is much greater than the AlO/HfO device (Comparative Example). These results show that even though HZO and HfO₂ both serve as charge capture layers, the presence of ferroelectricity may also significantly affect memory performance.

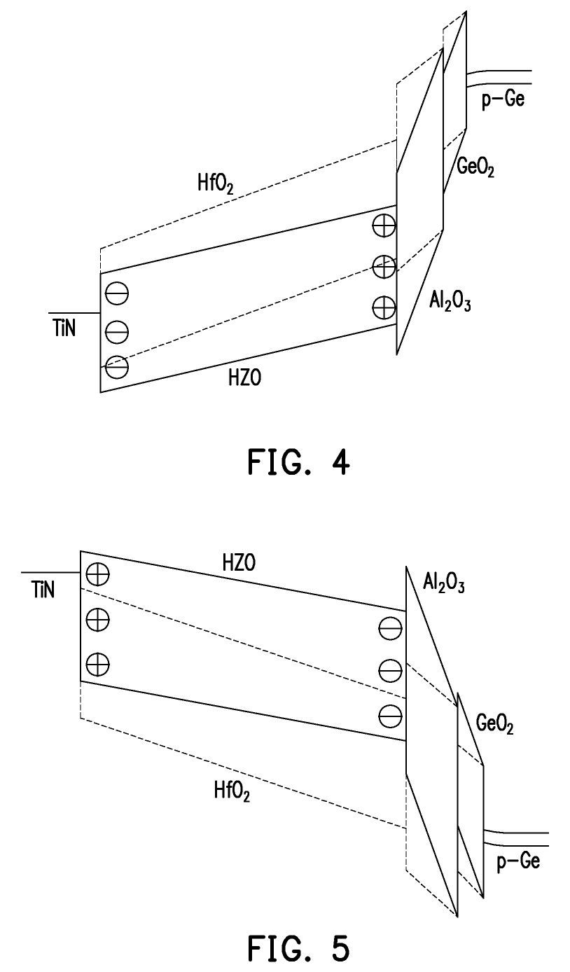

FIGS. 4 and 5 are band diagrams simulating the gates in Experimental Example 1 and Comparative Example respectively under a positive bias voltage and a negative bias voltage.

In FIG. 4, a higher Pr value may enhance an electric field of the tunneling oxide layer, thereby promoting electrons to be injected from the substrate into the HZO layer, shortening an electron tunneling distance, and increasing charge capture efficiency. In an erase operation of FIG. 5, the enhanced electric field also facilitates to release electrons from the HZO layer to the substrate.

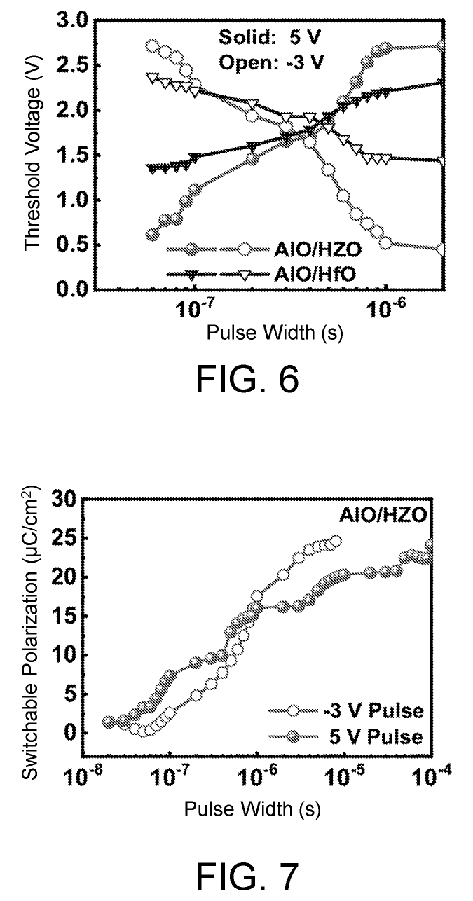

FIG. 6 shows a curve graph of threshold voltages (Vt) changing with a 5 V/-3 V pulse width according to Experimental Example 1 and Comparative Example. From FIG. 6, it may be obtained that under a same pulse condition, Experimental Example 1 exhibits a higher Vt drift than similar devices. Under the 5 V/-3 V pulse for 1μs, Experimental Example 1 shows a Vt offset of ~2.2 V. This means that a negative bias voltage may increase an operating speed, and a large Vt change may obtain a larger MW. FIG. 7 is a curve graph of switchable polarizations changing with the 5 V/-3 V pulse width according to Experimental Example 1. The switchable polarization of 16.4 μC/cm² may be obtained under the 5 V/-3 V pulse for 1 μs.

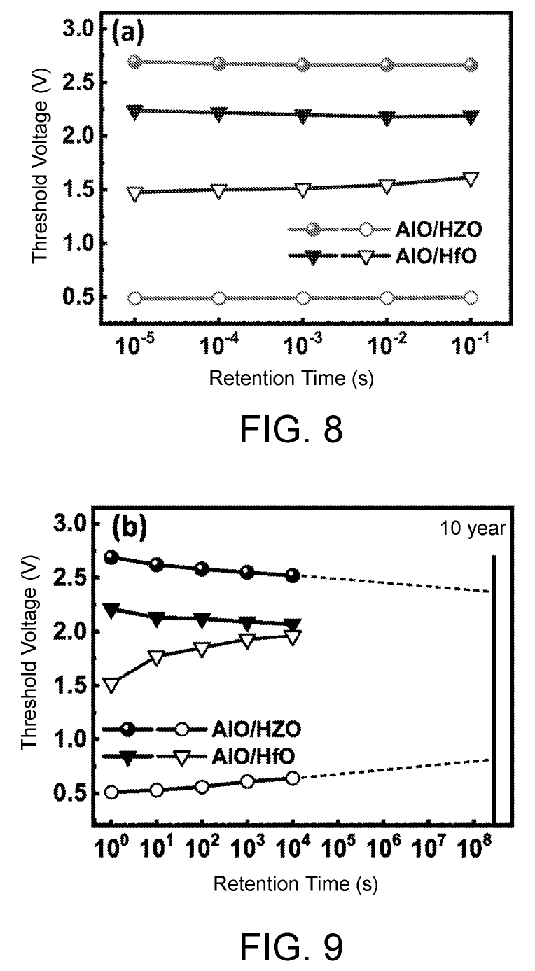

FIG. 8 is short-term retention capability results of Experimental Example 1 and Comparative Example. FIG. 9 is long-term retention capability results of Experimental Example 1 and Comparative Example.

From FIG. 8, it may be obtained that even within a short delay time of 10⁻⁵ s, both devices exhibit stable Vts. Moreover, a delay time of Experimental Example 1 is much shorter compared to a read delay of 1 s to 0.1 s of a current n-FeFET.

From FIG. 9, it may be obtained that Experimental Example 1 still maintains excellent data endurance even without a blocking layer. This is because the charge capture layer of Experimental Example 1 has ferroelectricity, and an electric dipole thereof may more effectively preserve captured electrons, extrapolating 10-year line may also implement an obvious MW of 1.6 V. In contrast, a long-term retention capability of Comparative Example is not good enough.

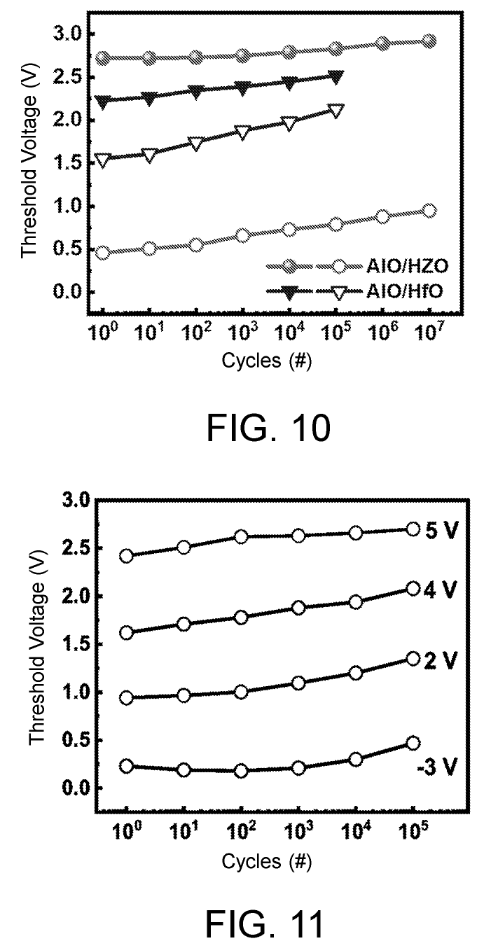

FIG. 10 is endurance test results of Comparative Example and Experimental Example 1. The foregoing test was performed on the AlO/HZO device and the AlO/HfO device under bipolar operating conditions of +5 V/1 μs and -3 V/1 μs. From FIG. 10, it may be seen that the AlO/HZO device may still maintain a MW at 2.0 V even after 10⁷ repeated operations. As for the AlO/HfO device, an initial MW is smaller, and the MW only has 0.39 V left after 10⁵ repeated operations.

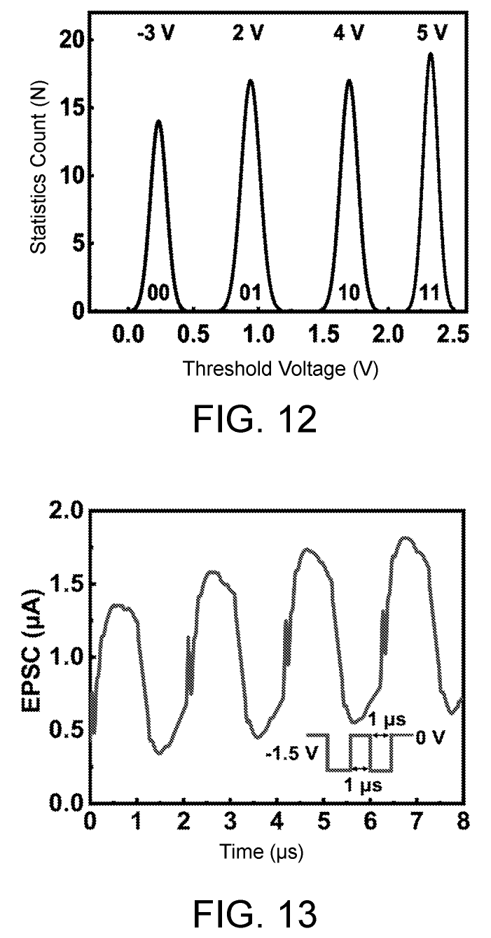

In the artificial intelligence era, high-density memory that can implement multi-level cells (MLC) and mimic synaptic behaviors is needed. To verify that the disclosure is adapted to MLC memory, results in FIG. 11 and a statistical count graph of FIG. 12 are obtained after the AlO/HZO device is cycled 10⁵ times in different Vt states.

From FIGS. 11 and 12, it may be obtained that the AlO/HZO device has a stable multi-bit storage capability, not only implementing four clearly distinguishable Vt states, but also maintaining a stable and consistent Vt read range after 10⁵ repeated operations. A distribution between each state has no overlap, ensuring identifiability.

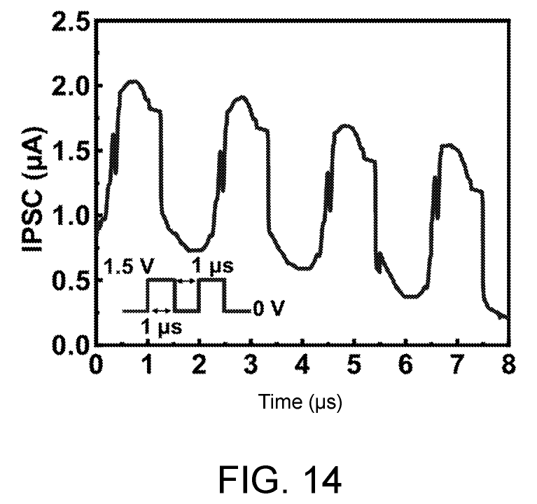

In addition, when continuous 1 μs and 1.5 V/-1.5 V pulses are applied on the gate (corresponding to a presynaptic neuron) of Experimental Example 1, a corresponding current change may be observed at the drain (corresponding to a postsynaptic neuron) and recorded in FIGS. 13 and 14.

FIG. 13 is an excitatory postsynaptic current (EPSC) change. FIG. 14 is an inhibitory postsynaptic current (IPSC) change. From FIGS. 13 and 14, an EPSC/IPSC similar to a neural system may be observed, proving a potential application value of the hybrid memory device of the disclosure in neuromorphic computing.

In summary, the disclosure uses the ferroelectric material to serve as the charge capture layer of flash memory, which can not only improve the operating speed of flash memory and effectively reduce the operating voltage, but also can omit the blocking oxide layer needed by general flash memory, thereby further reducing the operating voltage. Compared with current ferroelectric memory, the hybrid memory device of the disclosure may be free from the limitation of read delay, and has a larger memory window and multi-bit storage capability, and possesses a long-term retention capability, excellent endurance, and negligible read delay.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A hybrid memory device, comprising:
a semiconductor substrate;
a tunneling layer, disposed on the semiconductor substrate;
a ferroelectric storage layer, disposed on the tunneling layer to enhance an electric field of the tunneling layer, wherein the ferroelectric storage layer comprises a ferroelectric material;
a gate, disposed on the ferroelectric storage layer, wherein the gate is in direct contact with the ferroelectric storage layer; and
a plurality of doped regions, formed in the semiconductor substrate on both sides of the gate.

2. The hybrid memory device according to claim 1, wherein the ferroelectric material comprises hafnium oxide doped with a metal.

3. The hybrid memory device according to claim 1, wherein the semiconductor substrate comprises a silicon substrate or a germanium substrate.

4. The hybrid memory device according to claim 1, wherein the tunneling layer comprises a single-layer or multi-layer structure.

5. The hybrid memory device according to claim 1, wherein the gate comprises a metal gate or a titanium nitride gate.

6. The hybrid memory device according to claim 1, wherein the tunneling layer comprises a high dielectric constant (high-k) material.
